(19) United States
(12) Patent Application Publication
(10) Pub. No.: US 2025/0173580 A1
(43) Pub. Date: May 29, 2025

(54) METHOD AND SYSTEM FOR VALIDATING A TRAINED ARTIFICIAL NEURAL NETWORK (ANN) ON THE BASIS OF A TEST DATA SET

(71) Applicant: Robert Bosch GmbH, Stuttgart (DE)

(72) Inventors: Konrad Groh, Stuttgart (DE); Matthias Woehrle, Bietigheim-Bissingen (DE)

(21) Appl. No.: 18/947,684

(22) Filed: Nov. 14, 2024

(30) Foreign Application Priority Data
Nov. 23, 2023 (DE) 10 2023 211 711.8

(51) Int. Cl. G06N 3/0985; G06F 11/28

(52) U.S. Cl. CPC G06N 3/0985; G06F 11/28

(57) ABSTRACT

A method and a system for validating a trained artificial neural network on the basis of a test data set.

### FIELD

The present invention relates to a method and a system for validating a trained artificial neural network (ANN) on the basis of a test data set.

### BACKGROUND INFORMATION

Trained artificial neural networks (ANNs) usually have a high degree of redundancy in their weights. This means that many weights are not absolutely necessary to allow efficient functioning of the neural network, in particular in the case of inference. Since the number of weights strongly influences the complexity of a network architecture underlying the artificial neural network and means that, as the number of weights increases, more and more computing power is required to run the artificial neural network, but also to train it, there is a need to keep the number of weights per layer of the network as low as possible, while still ensuring that the ANN functions efficiently.

In order to allow an evaluation of the quality and/or performance of ANNs, validation methods are desirable.

### SUMMARY

An object of the present invention is to provide a method and a system for validating a trained artificial neural network (ANN) on the basis of a test data set.

The object may be achieved by a computer-implemented method for validating a trained artificial neural network (ANN) on the basis of a test data set according to certain features of the present invention. The object may be achieved by a system for validating a trained artificial neural network (ANN) on the basis of a test data set according to certain features of the present invention.

In the present case, a method for validating a trained artificial neural network (ANN) on the basis of a test data set is specified. According to an example embodiment of the present invention, the method comprises the following steps:
providing the trained ANN with a network architecture, which represents an in particular non-linear, chained function by means of which a d-dimensional input space can be mapped to an N-dimensional output space, and further comprising a plurality of weights;
providing the test data set;
partitioning the d-dimensional input space into a plurality of cells on the basis of the network architecture of the ANN, wherein the individual cells can each be separated from one another in each case by at least one weight-specific hyperplane and/or hyperset;
checking whether at least one data point of the test data set is present in each of the cells in order to validate the ANN; and
if no data point is present in at least one of the cells, generating (S5) at least one new data point by means of a simulation model on the basis of cell parameters of the at least one of the cells in order to complete the test data set.

The present invention generates a partitioning of the input space into cells. In particular, the predicted class is constant in each cell. The present invention checks whether a data point is present in each cell. If this is the case, the algorithm or validation method preferably ends. If this is not the case, the simulation model is given the parameters of the cells without a data point. The simulation model then preferably generates at least one new data point in the cell(s) concerned. If necessary, the ANN is retrained iteratively with the newly generated data or data points. Preferably, new test data are generated, on the basis of which the retrained ANN can be evaluated or validated again.

It is understood that the steps according to the present invention as well as other optional steps do not necessarily have to be carried out in the order shown, but can also be carried out in a different order. Other intermediate steps can also be provided. The individual steps can also comprise one or more sub-steps without departing from the scope of the method according to the present invention.

In other words, the method according to the present invention partitions the d-dimensional input space of the ANN into a finite number of cells (“faces”). In or within each of these cells, an output of the ANN is preferably constant if the function of the ANN is to solve a classification task. In or within each of these cells, an output of the ANN is preferably linear if the function of the ANN is to solve a regression task. Pruning of the ANN takes place by means of the method.

A hyperplane is a mathematical term defined in a multidimensional space. In a two-dimensional space, a hyperplane is a straight line; in a three-dimensional space, it is a plane. In general, a hyperplane in an n-dimensional space is an (n−1)-dimensional face that divides the space into two parts. In ANNs, hyperplanes are used to define classes or decision boundaries by dividing the space into regions corresponding to different categories or states.

A hyperset is an extension of the concept of a hyperplane. Instead of a single hyperplane, a hyperset is a collection of hyperplanes in the space. These hyperplanes can be used as a whole to define complex spatial structures. Hypersets are used in ANNs to model more complex decision boundaries that cannot be described simply by single hyperplanes.

The input space (also called feature space) refers to the space in which the input data of a neural network exist. Each dimension of the input space corresponds to a specific feature or property of the input data. For example, the pixel values of an image could form the input space in an image classification network.

The output space refers to the space of the output values of a neural network. This space depends on the type of network. In a classification network with multiple classes, the output space could contain vectors representing the probabilities for each class. In a neural network for regression, the output space could represent numerical values.

In a preferred embodiment of the present invention, the ANN has a d-dimensional number of input variables. Such input variables can comprise sensor signals, for example. The input variables can be preprocessed, for example normalized and/or transformed from a time domain to a frequency domain or from a frequency domain to a time domain and/or filtered and/or smoothed or similar. The term “d-dimensional” means that preferably d different signals are available as input variables. Thus, an input space of dimension d is spanned. The network architecture further has a plurality of bias terms. In an ANN, the bias term is preferably a constant that is added to the weighted inputs of each neuron before the, preferably non-linear, activation function is applied. It can be interpreted as a kind of shift that influences the activation of the neuron. The bias helps to control the activation range and the overall ability of the network to adapt to the data. The bias term allows a neuron to be activated even if all the weighted inputs are equal to zero. This allows the network to respond more flexibly to different patterns and relationships in the data. In a multilayer neural network, each neuron typically has its own bias value. Partitioning the d-dimensional input space into a plurality of cells on the basis of the network architecture comprises at least the following steps: determining hyperplanes and/or hypersets depending on the input variables, at least a subset of the plurality of weights and a subset of the plurality of bias terms. How exactly the partitioning of the input space as well as that of the subsequent spaces of the network layers is carried out is described in detail in the description of the drawings, to which explicit reference is made here.

In a preferred embodiment of the present invention, if at least one data point of the test data set is present in each of the cells, a validation result of the ANN is provided, on the basis of which a quality and/or goodness and/or performance of the ANN can be determined and/or evaluated. On the basis of the validation result, it can preferably be decided whether the ANN can be used in the inference, for example by comparing the validation result with a predetermined threshold value. This increases the performance and reliability of the ANN. In a preferred embodiment, the ANN is retrained on the basis of the completed test data set. Through retraining, the performance of the ANN is sustainably improved. This results in a reduced error rate in the inference of the ANN.

In a preferred embodiment of the present invention, an extended and/or new test data set is provided for the retrained ANN, on the basis of which new test data set another validation of the retrained ANN is carried out. In this way, the performance of the ANN can be improved continuously and/or iteratively.

In a preferred embodiment of the present invention, the retraining is carried out iteratively.

In a preferred embodiment of the present invention, the following applies to the d-dimensional input space: d=10, preferably d<10, particularly preferably d<6, where d is an element of the positive, natural number set. Preferably, the ANN is therefore a small-dimensional network. For ANNs of higher dimension, partitioning would only be possible with a disproportionately higher computational effort due to the large number of input variables.

In a preferred embodiment of the present invention, the ANN is part of a complex machine learning model. This allows a part or component of the complex model to be optimized. This leads to an improvement of the overall model.

In a preferred embodiment of the present invention, the simulation model is designed to generate at least one data point, in particular by data augmentation, on the basis of the cell parameters, in particular on the basis of the hyperplane information and/or hyperset information. The simulation model can be a data augmentation model, for example.

In a second aspect present invention, a system for validating a trained artificial neural network (ANN) on the basis of a test data set is provided. According to an example embodiment of the present invention, the system comprises a provisioning device that is designed to carry out the following steps: providing the trained ANN with a network architecture, which represents an in particular non-linear, chained function by means of which a d-dimensional input space can be mapped to an N-dimensional output space, and further comprising a plurality of weights; providing the test data set; and an evaluation and/or computing device that is designed to carry out the following steps: partitioning the d-dimensional input space into a plurality of cells on the basis of the network architecture of the ANN, wherein the individual cells can each be separated from one another in each case by at least one weight-specific hyperplane and/or hyperset; checking whether at least one data point of the test data set is present in each of the cells in order to validate the ANN; and, if no data point is present in at least one of the cells, generating at least one new data point by means of a simulation model on the basis of cell parameters of the at least one of the cells in order to complete the test data set.

The example embodiments mentioned for the method of the present invention apply in the same or a similar way to the system of the present invention.

The present invention also relates to a control and/or computing device that is designed to perform a regression task and/or a classification task by running the ANN provided, trained, validated and/or optimized according to the method of the present invention. The control and/or computing device can be included purely by way of example in an autonomous vehicle and/or a robotic system and/or an industrial machine. Such a control and/or computing device can be used, for example, as an embedded device in a plant or system. In general, the present method can be used particularly for small-dimensional artificial neural networks. For example, the present validated and/or optimized ANN can be used as a virtual sensor with up to ten, preferably up to 5-dimensional inputs. The ANN provided here can also be used for feature detection in larger ANNs, for example for autonomous edge detection. Other examples of virtual sensors in the vehicle are virtual temperature sensors (e.g. on the stator/rotor of an electric motor or on an injector magnet), mass estimators for an injection system, coking models and/or virtual sensors for exhaust gas concentrations. In principle, the present method or the ANN provided thereby can be applied to all virtual sensors that are used in cases of impossibility of installation, high cost pressure, or complex measurement setup for serial production.

In addition, the ANN validated and/or optimized and provided here can be used to determine a correction factor for calculation for the display of the current consumption of an engine in a vehicle. The present ANN offers an alternative to conventional methods that require “running in of an injector” and may not always work. This behavior can be parameterized in a map. In addition, increased EU requirements require the use of alternative methods. Thanks to the compactness and low complexity of the ANN validated and/or optimized here, such an alternative is provided.

In addition, the ANN validated and/or optimized and provided here can be used to detect a change point from a discrete gyroscope signal, for example for fall detection. It is advantageous in this case that the input vectors here are small-dimensional, and thus an application of the present optimization method can be carried out optimally in order to provide an optimized ANN.

In addition, the ANN provided here can be used as an edge filter in image processing. This can be explained using an excavator bucket as an example, wherein the ANN can be used as part of the control loop of the excavator bucket. The transfer function of the excavator joystick to the cylinder position of the bucket can be modeled using such an ANN optimized here. Preferably, small-dimensional networks with a simple network architecture, for example of the size 3-15-15-1 and/or 2-15-7-1, are considered in this case. For such small ANNs, the partitions can be determined in less than 5 seconds, for example.

In particular, due to its low dimensionality, the present ANN can be used as a surrogate function in which the ANN represents a solution of a partial differential equation, which cannot be calculated independently in real time.

According to an example embodiment of the present invention, a computer program having program code is also provided to carry out at least parts of the method according to the present invention in any of its embodiments when the computer program is executed on a computer. In other words, a computer program (product) comprising commands that, when the program is executed by a computer, cause the computer to carry out the method/steps of the method according to the present invention in one of its embodiments.

According to the present invention, a computer-readable data carrier having program code of a computer program is proposed to carry out at least parts of the method according to the present invention in any of its embodiments when the computer program is executed on a computer. In other words, the present invention relates to a computer-readable (memory) medium comprising commands that, when executed by a computer, cause the computer to perform the method/steps of the method according to the present invention in one of its embodiments.

The described embodiments and developments of the present invention can be combined with one another as desired.

Further possible embodiments, developments and implementations of the present invention also include combinations not explicitly mentioned of features of the present invention described above or in the following relating to the exemplary embodiments.

### BRIEF DESCRIPTION OF THE DRAWINGS

The figures are intended to impart further understanding of the example embodiments of the present invention. They illustrate example embodiments and, in connection with the description, serve to explain principles and concepts of the present invention.

Other embodiments of the present invention and many of the mentioned advantages are apparent from the figures. The illustrated elements of the drawings are not necessarily shown to scale relative to one another.

FIG. 1 shows exemplary hyperplanes for partitioning an input space.

FIG. 2 shows the diagram from FIG. 1 with additional coding information.

FIG. 3 shows an exemplary diagram of a completed partitioning with two-dimensional open sets.

FIG. 4 shows an exemplary diagram of open 1-dimensional sets.

FIG. 5 shows an exemplary diagram of three 0-dimensional sets.

FIG. 6 shows an exemplary diagram of a partitioning of a 10-dimensional input space of a first layer of an ANN.

FIG. 7 shows an exemplary diagram of a partitioning of a 10-dimensional input space of a second layer of an ANN.

FIG. 8 shows an exemplary flow diagram of an exemplary embodiment of the method of the present invention.

FIG. 9 shows an exemplary diagram of an input space of the first layer of an ANN.

FIG. 10 shows an exemplary diagram of an input space of the first layer of an ANN.

FIG. 11 shows an exemplary diagram of an input space of the second or a further layer of an ANN.

FIG. 12 shows an exemplary diagram of an input space of the second or a further layer of an ANN.

In the figures, identical reference signs denote identical or functionally identical elements, parts or components, unless stated otherwise.

### DETAILED DESCRIPTION OF EXAMPLE EMBODIMENTS

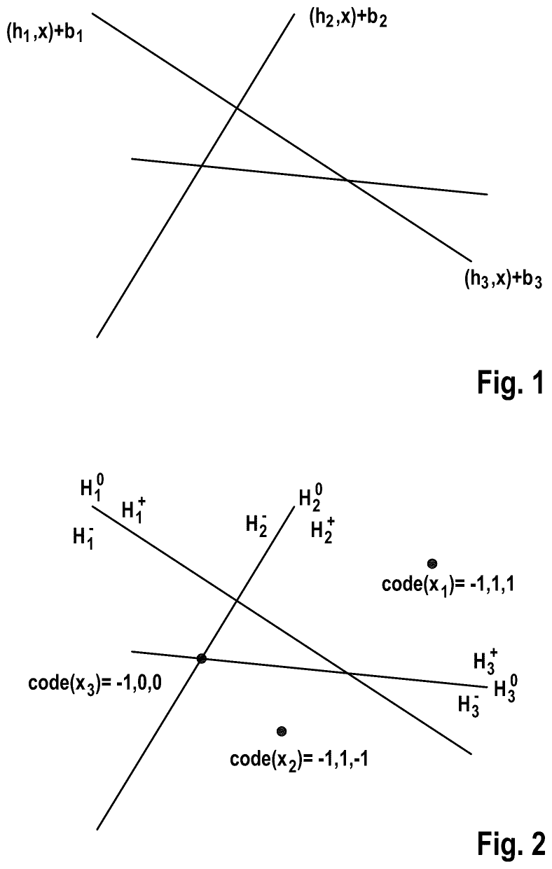

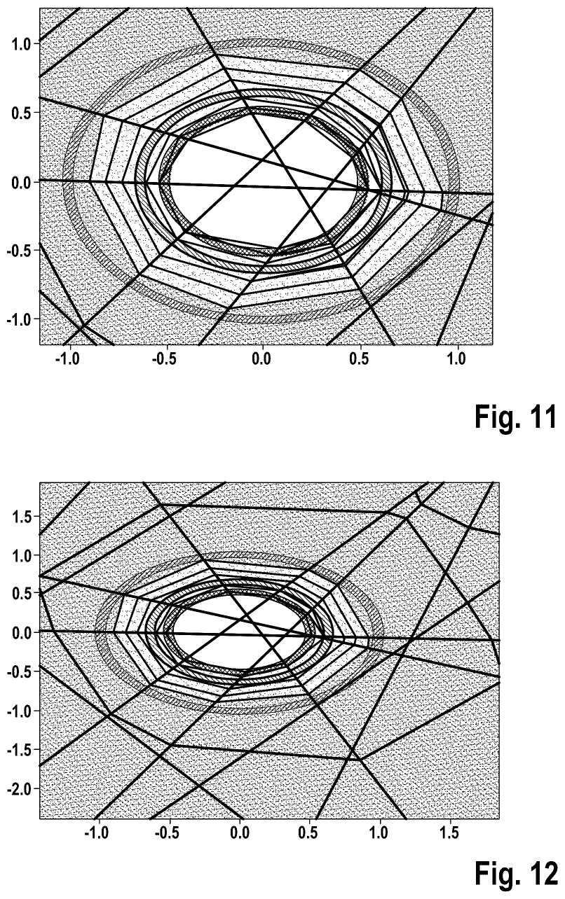

The partitioning of the input space is described in terms of its mathematical principles with reference to FIG. 1 to 7. The present invention is explained with reference to FIG. 8 to 12.

The partitioning according to the present method preferably considers a multilayer neural network ANN with ReLU nonlinearities as the activation function. This means that the ANN defines a function F: R^{m1}→R^{mk+1}.

The following applies:

$$F ( x ) = {A}^{k} ϕ ( {A}^{k - 1} ϕ ( {A}^{k - 2} … ϕ ( {A}^{2} ( ϕ ( {A}^{1} x + {b}^{1} ) ) + {b}^{2} ) + … ) + {b}^{k}$$

with weight matrices A¹, . . . , A^{k}, and bias terms b¹, . . . , b^{k}. Here, A¹ are matrices, i.e., linear mappings between real vector spaces A¹: R^{m1}, R^{m2}, A²: R^{m2}, R^{m3}, . . . , A^{k}: R^{mk}→R^{mk+1} and b¹ E R^{m2}, . . . , b^{k}∈R^{mk+1} are vectors of a real vector space.

Overall, F is preferably a chained mapping F: R^{m1}→R^{mk+1} of the m1-dimensional Euclidean space R^{m1} in the mk+1-dimensional Euclidean space R^{mk+1}.

To reduce the notation, d=m₁ and N=mₖ₊₁ is set, i.e., the network F: R^{d}→R^{N} examined here is a function of the d-dimensional Euclidean space R^{d} in the N-dimensional Euclidean space R^{N}.

If a regression is modeled, the description of the function F(x) is preferably terminated. The ANN then preferably returns the value F(x) as the output value or prediction value.

In the case of classification of the input signal x into mₖ₊₁ classes, a softmax function preferably follows the output F(x).

As a result, the components of F(x)=(f₁(x), f₂(x), . . . , fₘₖ₊₁(x)) are preferably positive, and normalized to one, i.e., for all input variables x the following applies: f₁(x), . . . , fₘₖ₊₁ (x)≥0 for all x and sum f₁(x)+ . . . +fₘₖ₊₁ (x)=1.

The classification is preferably carried out with an argmax function that returns the index of the vector g₁(x), . . . , gₘₖ₊₁ (x) at which the g (x) is maximal.

After the principles have been explained, the partitioning of the input space is described in more detail below. The layers of the ANN preferably partition the input space into cells. In the case of a classification network, it is preferable to distinguish between the first layer (input layer), middle layers (also subsequent layers or layers following the input layer), and last layer (also output layer).

In the first layer of the network, consisting of a pair of weight matrix A¹ and bias terms b¹, and a ReLU nonlinearity p (activation function), an input vector x is multiplied by the weight matrix A¹, the bias term b¹ is added, and the resulting vector A¹x+b¹ is fed to a component-by-component ReLU ϕ(A¹x+b¹). At the component level this means:

$${y}^{1} = ϕ ( {A}^{1} x + {b}^{1} ) = ϕ ( [ \begin{matrix}{a}_{11}^{1} & {a}_{12}^{1} & … & {a}_{1 d}^{1} \\ {a}_{21}^{1} & {a}_{22}^{1} & … & {a}_{2 d}^{1} \\ … & … & … & … \\ {a}_{m 1}^{1} & {a}_{m 2}^{1} & … & {a}_{md}^{1}\end{matrix} ] [ \begin{matrix}{x}_{1} \\ {x}_{2} \\ … \\ {x}_{d}\end{matrix} ] + [ \begin{matrix}{b}_{1}^{1} \\ {b}_{2}^{1} \\ … \\ {b}_{m}^{1}\end{matrix} ] ) =$$

$$[ \begin{matrix}ϕ ( {a}_{11}^{1} {x}_{1} + {a}_{12}^{1} {x}_{2} + … + {a}_{1 d}^{1} {x}_{d} + {b}_{1}^{2} ) \\ ϕ ( {a}_{21}^{1} {x}_{1} + {a}_{22}^{1} {x}_{2} + … + {a}_{2 d}^{1} {x}_{d} + {b}_{2}^{1} ) \\ … \\ ϕ ( {a}_{m 1}^{1} {x}_{1} + {a}_{m 2}^{1} {x}_{2} + … + {a}_{md}^{1} {x}_{d} + {b}_{m}^{1} )\end{matrix} ]$$

For easier legibility, d=m₁ and m=m₂ have been set.

In the following, the column vectors of A¹ with the vectors h¹, . . . , h^{m} are also included.

$${h}_{1} = [ \begin{matrix}{a}_{11}^{1} \\ {a}_{12}^{1} \\ … \\ {a}_{1 d}^{1}\end{matrix} ] , … , {h}_{m} = [ \begin{matrix}{a}_{m 1}^{1} \\ {a}_{m 2}^{1} \\ … \\ {a}_{md}^{1}\end{matrix} ]$$

These vectors and the bias term preferably each define open half-spaces.

$${H}_{1}^{-} := \{ x ∈ {R}^{{m}_{1}} \vert 〈 {h}_{1} , x 〉 + {b}_{1}^{1} < 0 \} , … , {H}_{m}^{-} := \{ x ∈ {R}^{{m}_{1}} \vert 〈 {h}_{m} , x 〉 + {b}_{m}^{1} < 0 \} \\ {H}_{1}^{+} := \{ x ∈ {R}^{{m}_{1}} \vert 〈 {h}_{1} , x 〉 + {b}_{1}^{1} > 0 \} , … , {H}_{m}^{+} := \{ x ∈ {R}^{{m}_{1}} \vert 〈 {h}_{m} , x 〉 + {b}_{m}^{1} > 0 \}$$

Furthermore, hyperplanes are introduced preferably for the purpose of partitioning.

$${H}_{1}^{0} := \{ x ∈ {R}^{{m}_{1}} \vert 〈 {h}_{1} , x 〉 + {b}_{1}^{1} = 0 \} , … , {H}_{m}^{0} := \{ x ∈ {R}^{{m}_{1}} \vert 〈 {h}_{m} , x 〉 + {b}_{m}^{1} = 0 \}$$

This system of half-spaces and hyperplanes partitions the input space Rⁿ preferably into cells. This relationship is shown by way of example in FIGS. 1 and 2. FIGS. 1 and 2 show three hyperplanes H₀, H₁, H₂, which are generated according to the above equations.

FIG. 2 shows the respective hyperplanes H₀, H₁, H₂ together with their open half-spaces. Furthermore, three exemplary points (vertices) with their particular coding are shown in FIG. 2.

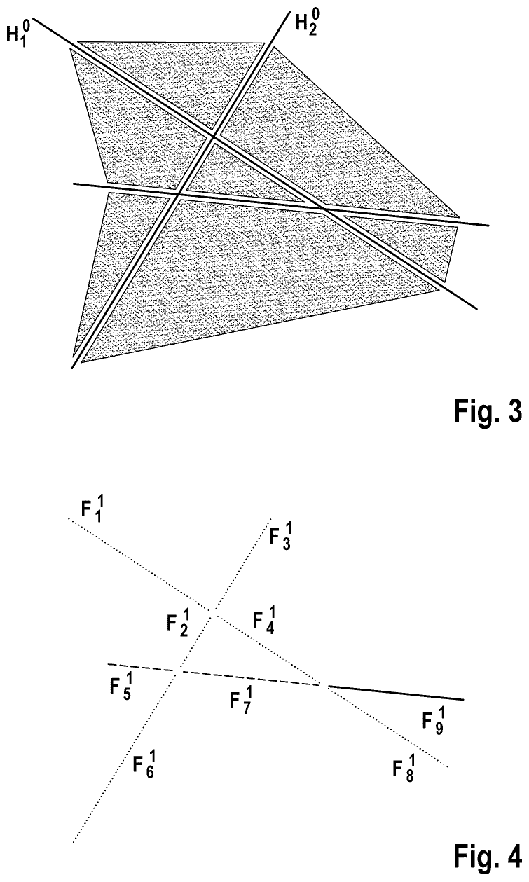

FIG. 3 shows the different cells generated by the hyperplanes H₀, H₁, H₂. In FIG. 4, a total of 7 cells are shown, each defining a two-dimensional open set.

In FIG. 4, one-dimensional cells are shown that define one-dimensional relative-open sets.

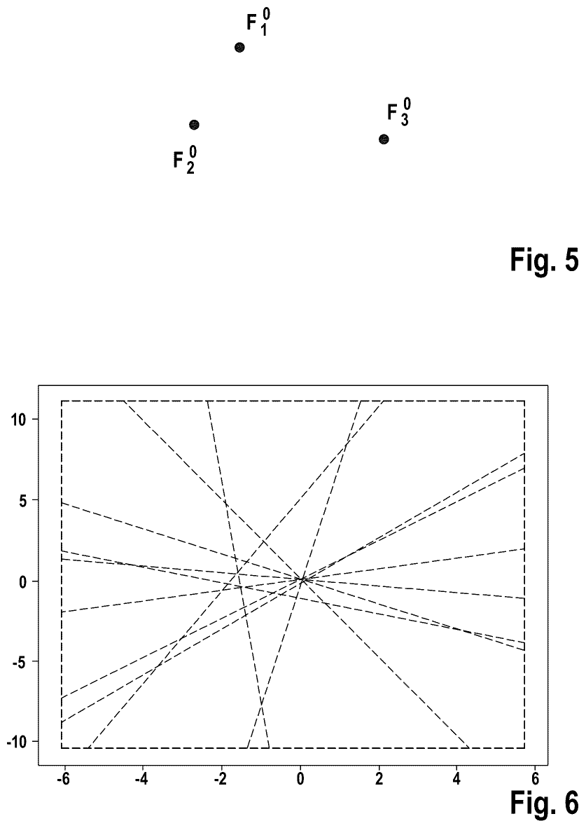

In FIG. 5, 0-cells are shown, which define zero-dimensional sets, i.e., vertices or points.

In other words, each element x∈R^{m1} is assigned a coding code(x)∈{−1,0,1}^{m} in such a way that a −1 is inserted at the k-th position if [symbol] h₁,x [symbol] +b₁¹<0, a 0 if [symbol] h₁,x [symbol] +b₁¹=0, and a +1 if h₁,x [symbol] +b₁¹>0. In this way, preferably each element of the input space is uniquely defined by a code.

The hyperplanes H₁⁰, H₂⁰, . . . , Hₘ⁰ of the first layer generate n-dimensional cells (or else n-faces). Here, the n-cells are the connected components of the complement of the union of the hyperplanes. Referring to FIG. 3, this means that the three lines represent the three hyperplanes, wherein a union of these lines defines a closed set (preferably as sets of points). The complement of this closed set is preferably an open set that divides the input space into connected components (the blue areas F₁², . . . , F₇²).

The (relatively open connected components) of the boundary of the n-faces are the (n−1)-cells (see FIGS. 3 and 4). The triangle F₄² preferably has a boundary consisting of three sides, which are preferably each defined by bounding hyperplanes or hypersets. These boundaries are preferably the three 1-cells.

Recursively, the k-cells are thus defined as the boundary of k+1-cells until 0-cells are formed at the end, which are preferably points of the input space.

### Connection to Neural Networks:

In each n-face, the output of the first layer of the neural ReLU ANN can be interpreted as a linear mapping.

From k-Layer to (k+1)-Layer

Each further layer of a ReLU ANN preferably further partitions the n-cells generated by the previous layers. Each n-cell should preferably be considered individually.

### Output Layer in a Regression:

In the case of a regression, the partitioning process is terminated. Here, the last layer or the output layer is preferably a linear mapping on the outputs of the penultimate layer. Preferably, no further partitioning of the input space is carried out.

### Output Layer in a Classification:

In the previous steps, a partitioning Pₖ of the input space into n-cells (in the input layer), (n−1)-cells (in the further layer), etc. was generated. The n-cells are also partitioned in the last layer, the output layer. Preferably, all n-cells are run through, wherein the following steps can be carried out:
1. A matrix-vector pair L, l that describes a linear relationship in an n-cell is defined. This is done, for example, as follows:
   a. An inner point x̌ of the n-cell is determined, for example by forming a common center of the vertices of the n-cells.
   b. For each layer, the active features are preferably determined. Furthermore, linear mapping and bias term are preferably determined interactively as follows:
      i. A¹x̌+b¹ is formed.
      ii. The rows in which the vector A¹x̌+b¹ is negative are determined.
      iii. A new matrix-vector pair [symbol] , [symbol] is formed, wherein [symbol] corresponds to the matrix A¹, preferably with the only difference that A¹x̌+b¹ is negative on the rows of the vector, and the rows of [symbol] are set to zero. In this way, ϕ(A¹x̌+b¹)= [symbol] x̌+ [symbol] . applies for the selected point x.
      iv. This is then carried out analogously for the other layers of the ANN:
      v. Preferably, a A²(ϕ(A¹x̌+b¹))+b² is formed, wherein the rows in which the vector is negative A²(ϕ(A¹x̌+b¹))+b² are determined.
      vi. A new matrix-vector pair [symbol] , [symbol] is formed, wherein [symbol] corresponds to the matrix A², except that A²(ϕ(A¹x̌+b¹))+b² is negative on the rows of the vector, and the rows of [symbol] are set to zero.
      vii. In this way, L and l can be introduced so that in the cell under investigation the following applies:

$$Lx + l = {A}^{k} ϕ ( {A}^{k - 1} ϕ ( {A}^{k - 2} … ϕ ( {A}^{2} ( ϕ ( {A}^{1} x + {b}^{1} ) ) + {b}^{2} ) + … ) + {b}^{k} .$$

2. From the matrix-vector pair L, l, a new matrix-vector pair (H, d) is then determined as follows:
   a. A matrix H, initialized with zeros, of size (0.5*number of classes*(number of classes−1))×d, and a vector d, initialized with zeros, of length 0.5*number of classes*(number of classes−1)) is formed.
   b. All combinations of two elements of the possible output classes are run through.
      i. For two classes 1,2 there is only one possible combination (1,2)
      ii. For three classes 1, 2, 3 there are three possible combinations (1,2), (1,3), (2,3)
      iii. For four classes 1, 2, 3, 4 there are six possible combinations (1,2), (1,3), (1,4), (2,3), (2,4), (3,4) etc.
   c. For each combination i, j, the following differences of the i-th column vector from the j-th column vector of L are formed, and analogously to this the difference of the i-th entry of the bias from the j-th entry of the bias is formed.
3. The cell is then further partitioned by this matrix H and bias term b.
4. Due to the construction, the class of the network determined by the argmax function becomes constant in each cell. The matrix H and the bias term identify the locations in the input space where F(x) has two components of equal size; these are the class boundaries of the neural network.

Thus, the partitioning of the input space into cells or faces was described above, wherein the ANN is constant in each cell (i.e., each n-face) of the partitioning.

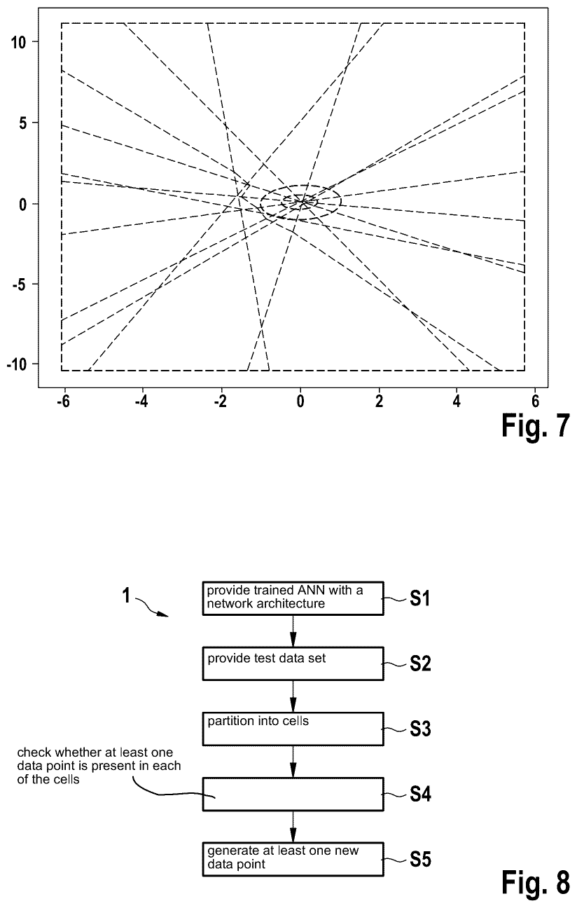

FIGS. 6 and 7 show further examples of the partitioning described above. The exemplary partitionings of the input space are shown using a 2->10->5->4 classification ANN. FIG. 6 shows a partitioning of the input space by the first layer. Ten hyperplanes generated by the weight matrices and bias terms are shown. FIG. 7 shows the partitioning of the input space after the second layer. Each 2-cell partitioning in FIG. 7 is further partitioned by five hyperplanes of the second layer. It is also possible in principle that the second layer has no (partitioning) effect in a cell.

FIG. 8 shows a flow diagram of an exemplary embodiment of the present method. In any embodiment, the method can be carried out at least in part by a system 1, which for this purpose can comprise a plurality of components not shown in more detail, for example one or more provisioning devices and/or at least one evaluation and computing device. It is self-evident that the provisioning device can be designed together with the evaluation and computing device, or can be different therefrom. Furthermore, the system can comprise a storage device and/or an output device and/or a display device and/or an input device.

According to the present invention, the computer-implemented method comprises at least the following steps:
providing (S1) the trained ANN with a network architecture, which represents an in particular non-linear, chained function by means of which a d-dimensional input space can be mapped to an N-dimensional output space, and further comprising a plurality of weights;
providing (S2) the test data set;
partitioning (S3) the d-dimensional input space into a plurality of cells on the basis of the network architecture of the ANN, wherein the individual cells can each be separated from one another in each case by at least one weight-specific hyperplane and/or hyperset;
checking (S4) whether at least one data point of the test data set is present in each of the cells in order to validate the ANN; and
   if no data point is present in at least one of the cells, generating (S5) at least one new data point by means of a simulation model on the basis of cell parameters of the at least one of the cells in order to complete the test data set.

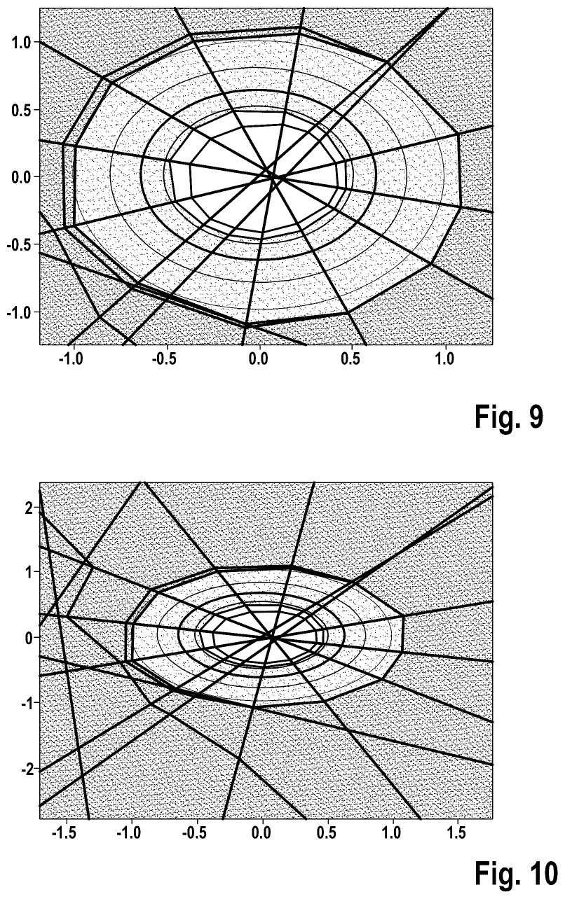

FIG. 9 to 12 show the present method by way of example for a partitioning of an input space by means of an ANN with two hidden layers, and for four output classes (network architecture: 2->10->10-4).

FIG. 9 shows an ANN with a diagram of a partitioned input space. FIG. 10 to 12 show ANNs that have been modified in relation to the ANN. A penultimate layer of the ANN preferably partitions the input space into 2-faces, 1-faces, etc. In order to be able to distinguish the test data, it is preferable to also consider the last layer. The circles preferably represent the test data of the ANN. The constant classes of the look-up table can be seen. It can further be seen how these classes fit the data.

1-12. (canceled)

13. A method for validating a trained artificial neural network (ANN) based on a test data set, the method comprising the following steps:
providing the trained ANN with a network architecture, which represents a non-linear chained function using which a d-dimensional input space can be mapped to an N-dimensional output space, and further including a plurality of weights;
providing the test data set;
partitioning the d-dimensional input space into a plurality of cells based on the network architecture of the ANN, wherein individual ones of the cells can each be separated from one another in each case by at least one weight-specific hyperplane and/or hyperset;
checking whether at least one data point of the test data set is present in each of the cells in order to validate the ANN; and
generating, when no data point is present in at least one of the cells, at least one new data point using a simulation model based on cell parameters of the at least one of the cells in order to complete the test data set.

14. The method according to claim 13, wherein the ANN has a d-dimensional number of input variables, wherein the network architecture further has a plurality of bias terms, and wherein the partitioning of the d-dimensional input space into a plurality of cells based on the network architecture includes at least the following step:
determining hyperplanes and/or hypersets depending on the input variables, at least a subset of the plurality of weights and a subset of the plurality of bias terms.

15. The method according to claim 13, wherein, when at least one data point of the test data set is present in each of the cells, a validation result of the ANN is provided, based on which a quality of the ANN can be determined.

16. The method according to claim 13, wherein the ANN is retrained based on the completed test data set.

17. The method according to claim 16, wherein an extended and/or new test data set is provided for the retrained ANN, wherein, based on the extended and/or new test data set, a validation of the retrained ANN is carried out.

18. The method according to claim 16, wherein the retraining is carried out iteratively.

19. The method according to claim 13, wherein the following applies to the d-dimensional input space: d<=10, where d is an element of a positive natural number set.

20. The method according to claim 13, wherein the ANN is part of a complex machine learning model.

21. The method according to claim 13, wherein the simulation model is configured to generate at least one data point, by data augmentation, based on the cell parameters, including based on the hyperplane information and/or hyperset information.

22. A system for validating a trained artificial neural network (ANN) based on a test data set, the system comprising:
a provisioning device is configured to carry out the following steps:
providing the trained ANN with a network architecture, which represents a non-linear chained function using which a d-dimensional input space can be mapped to an N-dimensional output space, and further including a plurality of weights, and
providing the test data set; and
an evaluation and/or computing device configured to carry out the following steps:
partitioning the d-dimensional input space into a plurality of cells based on the network architecture of the ANN, wherein individual ones of the cells can each be separated from one another in each case by at least one weight-specific hyperplane and/or hyperset,
checking whether at least one data point of the test data set is present in each of the cells in order to validate the ANN, and
generating, when no data point is present in at least one of the cells, at least one new data point using a simulation model based on cell parameters of the at least one of the cells in order to complete the test data set.

23. A non-transitory computer-readable data carrier on which is stored program code of a computer program for validating a trained artificial neural network (ANN) based on a test data set, the computer program, when executed by a computer, causing the computer to perform the following steps:
providing the trained ANN with a network architecture, which represents a non-linear chained function using which a d-dimensional input space can be mapped to an N-dimensional output space, and further including a plurality of weights;
providing the test data set;
partitioning the d-dimensional input space into a plurality of cells based on the network architecture of the ANN, wherein individual ones of the cells can each be separated from one another in each case by at least one weight-specific hyperplane and/or hyperset;
checking whether at least one data point of the test data set is present in each of the cells in order to validate the ANN; and
generating, when no data point is present in at least one of the cells, at least one new data point using a simulation model based on cell parameters of the at least one of the cells in order to complete the test data set.
